(19) United States
(12) Patent Application Publication
(10) Pub. No.: US 2007/0138506 A1
(43) Pub. Date: Jun. 21, 2007

(54) Nitride metal oxide semiconductor integrated transistor devices

(76) Inventor: Walter David Braddock, Rochester, MN (US)

Correspondence Address: NEIFELD IP LAW, PC, 4813-B EISENHOWER AVENUE, ALEXANDRIA, VA, 22304, US

(21) Appl. No.: 10/579,537

(22) PCT Filed: Nov. 17, 2004
(86) PCT No.: PCT/US04/38582

§ 371 Date: May 16, 2006

Related U.S. Application Data
(60) Provisional application No. 60/520,322, filed on Nov. 17, 2003.
(60) Provisional application No. 60/527,306, filed on Dec. 8, 2003.

(51) Int. Cl. H01L 31/00; H01L 29/739

(52) U.S. Cl. 257/192; 257/201; 257/194

(57) ABSTRACT

A self-aligned enhancement mode or depletion mode nitride based metal-oxide-compound semiconductor field effect transistor (10) includes a gate insulating structure comprised of a first oxide layer that in comprised of gallium oxides or indium oxides compounds (30) positioned immediately on top of the nitride compound semiconductor structure, and a second insulating layer comprised of either (a) oxygen and rare earth elements, (b) gallium oxygen and rare earth elements, or (c) gallium+indium and rare earth elements positioned immediately on top of said first layer. Together the lower indium oxide or gallium oxide layer and the second insulating layer form a epitaxial oxide gate insulating structure. The gate insulating structure and underlying compound semiconductor layer (15) meet at an atomically abrupt interface at the surface of with the compound semiconductor wafer structure (14) that is based on the nitride family of compound semiconductors. The first oxide layer serves to passivate and protect the underlying compound semiconductor surface from the second insulating layer and atmospheric contamination. A refractory metal gate electrode layer (17) is positioned on upper surface (18) of the second insulating layer. The refractory metal is stable on the second insulating layer at elevated temperature. Self-aligned source and drain areas, and source and drain contacts (19, 20) are positioned on the source and drain areas (21, 22) of the device. Multiple devices are then positioned in proximity and the appropriate interconnection metal layers and insulators are utilized in concert with other passive circuit elements to form an integrated circuit structure. Finally, NMOS and PMOS nitride based devices are positioned in proximity to for a complementary metal oxide semiconductor integrated circuit in nitride based compound semiconductors.

### STATEMENTS REGARDING FEDERALLY SPONSORED RESEARCH OR DEVELOPMENT

This invention was made with the support by the United States Government under US navy Contract number NB00178-03-C-3011. The United States may have certain rights to the invention.

### FIELD OF THE INVENTION

The present invention generally relates to high power and/or high speed integrated circuits in the compound semiconductor field utilizing field effect transistors and more specifically to enhancement mode self-aligned metal-oxide-compound semiconductor transistors, depletion mode self-aligned metal-oxide-compound semiconductor transistors, NMOS and PMOS transistors, methods of materials growth and fabrication of these transistors, and the ultra large scale integration of said transistors forming integrated circuits, including NMOS, PMOS and CMOS integrated circuits formed in nitride based compound semiconductors.

### BACKGROUND OF THE INVENTION

The main barrier to the realization of a desirable Complementary Metal Oxide Semiconductor (CMOS) technology in gallium nitride, indium nitride and aluminum nitride semiconductors is the absence of a proper gate insulator and gate passivation layer that passivates the surface of a compound semiconductor structure reducing the interface state trap density and simultaneously provides for sufficient insulating properties that are necessary for low gate leakage currents in the picoamp to nanoamp range required by very large scale (VLSI) and ultra large scale (ULSI) integrated circuit technology. Field effect transistor (FETs) widely used in the III-V semiconductor industry typically employ metal gates placed directly on the compound semiconductor structure forming Schottky gate contacts that are have quiescent-state leakage currents exceeding many microamps. Large leakage currents are especially true in certain GaN HEMT devices when operated at high voltages that can exceed 15V. The use of non-insulated metal gates placed directly onto compound semiconductor technology further results in individual transistors and integrated circuits that have excessively high power dissipation, reduced transconductance especially at microwave frequencies, low threshold voltage, reduced logic swing and the inability to operate on a single power supply, and generally limited performance characteristics. The high magnitude of the quiescent leakage current limits the maximum integration of AlN, GaN, and InN based devices to circuits of several thousand transistors.

In contrast, conventional silicon technology has a very mature and useful complementary metal oxide semiconductor (CMOS) technology. In silicon CMOS technology an insulating layer may be formed at the silicon structure surface without the introduction or formation of an undue density of electronic traps in the combined silicon/SiO₂ semiconductor structure. Recently alternative gate insulators, often called, high-K gate dielectrics, by those skilled in the art have been a topic of research on silicon, and these alternative gate insulators are deposited in some ultrahigh vacuum deposition technique. Typically the trap density in the silicon/SiO₂ materials system observed before hydrogen passivation of any traps or defects is in the 10¹⁰-10¹¹ cm²/eV at the center of the band gap. Thus, the insulating layer (SiO₂ or SiO₂+dielectric or alternative gate dielectric or high-K dielectric) formed at the silicon wafer surface may act as a passivating layer that occupies dangling bonds at the silicon surface, reduces the interface state trap density in the energy gap and protects the semiconductor surface from environmental contamination, non-planar oxidation or reaction of impurities and the associated formation of electronic traps. It is well know by those skilled in the art that the electronic traps that are observed midway between the conduction band and valence band are caused by the disruption of the crystal symmetry at a semiconductor surface. Thus, excessive intermixing or disruption of the semiconductor surface at the interface between the semiconductor structure and any upper layer or layers will introduce increased electronics traps into the semiconductor structure.

The simultaneous integration of many millions of transistors is possible at high integration densities using silicon CMOS technology. These ultra high integration densities and levels cannot be obtained using metal, Schottky-style gates that are not insulated from the compound semiconductor structure in GaN HEMTs or FETs. Thus Si CMOS technology offers significant advantages in terms of the low gate leakage of individual transistors, and circuit integration level and complex circuit functionality and manufacturing cost.

However when compared to silicon technology, compound semiconductors such as GaN, InN, AlN and their alloys exhibit faster and more optimized speed/power performance and efficiency and a higher saturated electron velocity. The market acceptance of these GaN and AlN integrated circuits remains low because of the low transconductance at microwave frequencies in nitride based BFETs and HEMTs. Also, high gate leakage in nitride MESFETs and HFETs and the lack of ability to demonstrate high integration densities does not allow for the formation of circuits with the functional complexity and low amounts of operating power required by many commercial applications. Thus, silicon CMOS dominates the field of low power high performance analog and digital integrated circuitry, and circuits based upon GaN, InN, AlN and related nitride alloy semiconductors cannot successfully penetrate this market.

What is needed is a nitride semiconductor surface state passivation structure that includes insulatong layers with an improved sharpness and abruptness at the nitride semiconductor-passivation layer interface. What is needed are new and improved compound semiconductor field effect transistors (FET). What is also needed are new and improved compound semiconductor FETs using metal-oxide-semiconductor junctions (MOSFET). What is also needed are new and improved compound semiconductor MOSFETs using a self-aligned gate structure. What is also needed are new and improved self-aligned compound semiconductor MOSFETs using enhancement mode and depletion mode operation. What is needed are new and improved NMOS and PMOS transistors formed in nitride based compound semiconductors. What is also needed are new and improved self-aligned compound semiconductor MOSFETs with stable and reliable device operation. What is also needed are new and improved self-aligned compound semiconductor MOSFETs which enable optimum compound semiconductor device performance. What is also needed are new and improved self-aligned compound semiconductor MOSFETs with optimum efficiency and output power for RF and microwave applications. What is also needed are new and improved self-aligned compound semiconductor MOSFETs for use in complementary circuits and architectures. What is also needed are new and improved self-aligned compound semiconductor MOSFETs for high power/high performance complementary circuits and architectures. What is also needed are new and improved self-aligned compound semiconductor MOSFETs which offer the design flexibility of complementary architectures. What is also needed are new and improved self-aligned compound semiconductor MOSFETs which keep interconnection delays in ultra large scale integration under control. What is needed are new and useful complementary integrated circuits where each individual transistor has a leakage current approaching 10⁻¹² amp. What is needed is a truly useful integrated circuit technology for InN, AlN, and GaN that allows for the useful and economical operation of ULSI digital integrated circuits, analog circuits and mixed signal circuits in nitride compound semiconductors. What is needed are new and improved compound semiconductor MOSFET integrated circuits with very low net power dissipation. What is needed are new and improved ohmic contacts that employ lower resistance materials that are formed by etching and epitaxial regrowth to avoid the use of ion implantation in nitride-based transistor structures. What is needed are new and improved compound semiconductor MOSFET devices with low gate leakage currents that may be integrated together to form ultra large scale integrated circuits that include millions of transistors. What is needed are new and improved complementary MOSFET devices and circuits in compound semiconductors that allow the direct use, transfer and application of silicon CMOS design that already exits in the art. What is needed are new and improved nitride based compound semiconductor MOSFETS that do not have a degraded transconductance as compared to the measured DC transconductance of the BFET. What is needed is a new and improved nitride based compound semiconductor MOSFET that does not employ a field plate or second gate finger for proper operation or delivery of microwave power to an antenna or other microwave or RF load.

What is also needed are new and improved methods of fabrication of self-aligned compound semiconductor MOSFETs. What is also needed is new and improved methods of fabrication of self-aligned compound semiconductor MOSFETs that are compatible with established complementary GaAs heterostructure FETs technologies. What is also needed are new and improved compound semiconductor MOSFETs which are relatively easy to fabricate and use.

### SUMMARY OF THE INVENTION

A first aspect of the present invention generally relates to the interface between the nitride based compound semiconductor structure and the gate insulating structure. It is well known to those skilled in the art that for best results the abruptness of the interface between the compound semiconductor structure and the passivating+insulating layer adjacent to the compound semiconductor structure should be reduced to one atomic layer in order to reduce the density of electronic traps in the resulting metal oxide semiconductor transistor device. If the interface between the compound semiconductor structure and the passivating and insulating layer varies by 3 or more atomic layers the electronic traps density will rise to levels that will cause the electrical behavior of the resulting transistor structure to be irreproducible due to charging and discharging of a large number of electronic traps. If the operation of a transistor is not reproducible as a function of voltage and current, the transistor is not useful. The abruptness of the interface between the compound semiconductor structure and the gate insulating structure may be improved by epitaxially growing the compound semiconductor structure before the oxide is deposited. A compound semiconductor structure with an atomically smooth upper surface is most desirable. The smoothness of a compound semiconductor growth during epitaxial growth processes such a Molecular Beam Epitaxy, Chemical Beam Epitaxy, Metal Organic Chemical Vapor Deposition, and related techniques may be improved by reducing the overall epitaxial growth rate while maintaining the substrate temperatures. For example in molecular beam epitaxy it is most common to produce nitride based compound semiconductor epitaxial layered structures at growth rates of between 0.1-3 angstroms per second. The interfaces produced by compound semiconductor epitaxial wafer growths that proceed at this rate and higher rates often lead to compound semiconductor surfaces that have a roughness of more than 1-3 atomic layers as observed by techniques such as Reflection High Energy Electron Diffraction (RHEED), atomic force microscopy, and scanning tunneling microscopy. Increased growth surface roughness have been observed in the RHEED features when the epitaxial layer growth proceeds at rates above 1.5 angstroms per second. By reducing the growth rate of GaN, InGaN, AlN, and InN and other nitride based compound semiconductors to below 1 angstrom per second for surface layers of nitride based compound semiconductor structures including InGaN, GaN, AlN, InN and other nitride based compound semiconductor semiconductor surface roughness may be reduced.

A second aspect of the present invention generally relates to a gate insulating structure comprised of a multi-layer stack of gallium containing oxides that includes gallium oxide or indium oxide in the first passivating layer adjacent to the compound semiconductor structure and a second, third, fourth etc. . . . insulating layer comprised of gallium, oxygen and at least one rare-earth element.

A third aspect of the present invention generally relates to a gate insulating structure comprised of a multi-layer stack of gallium containing oxides that include gallium oxide in the first passivating layer adjacent to the compound semiconductor structure and second insulating layer comprised of oxygen and one or more rare earth elements not including gallium.

A fourth aspect of this invention is that oxygen and sulphur may be used interchangably in the passivation and insulating layers placed upon the nitride based compound semiconductor structures where the other elements in the passivation and insulating layers layer remain fixed. Normally, an ultra high vacuum technique called molecular beam epitaxy is used to form these gate insulating structures. During the epitaxial growth of such structures, interfacial smoothness may be monitored using an in-situ electron diffraction technique called Reflection High Energy Electron Diffraction (RHEED) to monitor the smoothness of the interface formed between the gate insulating structures and the compound semiconductor material. If the RHEED features are linearly sharp possessing a minimum of dots or discontinuous structure, those skilled in the art of RHEED would identify that the interface remains atomically smooth with a maximum abruptness during the deposition of oxide materials on the compound semiconductor structure. The RHEED features slowly disappear as the oxide deposition proceeds on the compound semiconductor structure showing that the materials pass from crystalline structure in the compound semiconductor, to oxide structure that has long range 2D order in the first 1-9 monolayers of oxide, to an amorphous-like structure as the deposition proceed for the next 25 angstroms, to an amorphous structure within 75 angstroms of total oxide structure growth. Previously, utilizing only Ga-oxides during deposition the RHEED pattern is observed to possess a discontinuous (i.e. non-streaky) pattern before its disappearance as the oxide thickness increases. During deposition of the initial gallium oxygen layer, the addition of small fractional amounts of indium oxygen compounds (<1%) induces a more favorable streaky-type pattern in the RHEED as disappearance of the pattern continues with increased oxide layer thickness.

A fifth aspect of the present invention generally relates to the abruptness of the interface between the compound semiconductor and the gate insulating structure. In particular, using the RHEED technique, a diffraction pattern remains more linear in nature if indium oxide is co-deposited with the gallium oxide compound in the initial passivation layer placed just adjacent to the compound semiconductor structure. The phenomenon of indium nitride based compounds smoothing the epitaxial growth surface of compound semiconductors such as Gallium Nitride during semiconductor epitaxial growth has been discussed by M. Asif Khan in IEEE Electron Device Letters, Volume 21, Number 2, page 63, February 2000.

A sixth aspect of this invention generally relates to the use of indium oxide compounds for the manufacturing of improved and more abrupt interfaces between the gate insulating structure and the compound semiconductor surface. The addition of fractional amounts of indium oxide less than 11% by volume in gallium oxide layers improves the interface abruptness between a compound semiconductor structure and the initial indium gallium oxide passivation layer that forms the initial and lowest layer of a gate insulating structure, without eliminating the nominally semiconducting properties of the indium oxide, gallium oxide, or indium gallium oxide layer initially deposited upon the compound semiconductor structure surface.

A seventh aspect of the present invention generally relates to a method for improving the smoothness of the surface of the compound semiconductor structure by incorporating interruptions in the epitaxial growth under ultra high vacuum conditions, and then initiate growth by alternately exposing the surface of the compound semiconductor to ½ monolayers of a group III element (i.e. Ga, In, Al, Ti) followed by the exposure of ½ a monolayer of a group V element (i.e. N) for the case of III-V nitride compound semiconductor structures. This aspect of compound semiconductor growth is referred to as migration enhanced epitaxy and is used by those skilled in compound semiconductor growth techniques of Molecular Beam Epitaxy, Metal Organic Chemical Vapor Deposition, Chemical beam Epitaxy, UHV CVD, and the related epitaxial growth techniques.

An eight aspect of the invention includes the use of a native AlN substrate that is more closely lattice matched to the GaN, AlGaN and InGaN layers in a nitride based heterojunction MOSFET, PHEMT or HFET that utilizes a nitride transistor structure. The use of a native AlN substrate allow for the elimination of a buffer layer that can possess a high relative density of charge traps that reduce the microwave performance of the device that is typically refered by those skilled in the art as microwave dispersion.

A ninth aspect of the invention is the use of mainly AlN layers with the exception of an AlGaN or InGaN channel so that only the channel of the transistor and the epitaxially deposited gate oxide are strained with respect to the AlN substrate of the transistor device structure. In addition it is most desirable configuration of the strain is such that the channel strain and epitaxial oxide strain are at least partially offsetting through the use compressive-type and tensile-type strain in one layer vs the other layer and substrate.

A tenth aspect of the invention is that the gate oxide that is formed from multiple layers is completely pseudomorphic and crystalline with respect to the underlying nitride based compound semiconductor layers that form the nitride compound semiconductor MOSFET device.

An eleventh aspect of the invention is the formation of selectively regrown ohmic contact regions of the device that allow for both a lower ohmic contact in the nitride MOSFET device and also the proper sense of charge in the channel of the device as well. These regrown ohmic contact regions may either be formed as n-type or p-type regions to allow for the integrated NMOS and PMOS devices in the same circuit. The regrowth step may be proceeded with a chemical etching step or plasma etching step that allows heavily doped regions to be placed lower in the epitaxial layers of the device structure while forming good quality ohmic contacts. In addition, the regrown ohmic contacts may be placed directly on the top surface of the top layer of the nitride based epitaxial structure and allowed to be formed in a manner that extends above the plane of the epitaxial gate oxide and even the gate metal that is immediately above the gate oxide structure of the transistor.

A twelfth aspect of the device is the use of a binary nitride, GaN or AlN or InN, layer on the upper most portion of the nitride based layer structure. The binary layer of GaN, AlN, or InN allows for the formation of a more stable binary oxide in an abrupt and smooth manner on the nitride semiconductor layer structure contained in the MOSFET device. It is most important to realize that compound of N—O are gaseous and volatile at room temperature and at elevated temperatures used during epitaxial growth and that the gaseous nature of these largely N—O-metal compounds allows for the fractional distillation of a stable initial oxide layer such as Ga2O3 or other Ga-oxide layer or In-oxide or In2O3 at the interface between the nitride semiconductor and the epitaxial gate oxide structure that together form a MOSFET Device structure.

A thirteenth aspect of the device is the simultaneous integration of NMOS and PMOS type nitride MOSFET devices that allows for the formation of a Complementary Metal Oxide Semiconductor type of circuit structure utilizing nitride based compound semiconductors.

A fourteenth aspect of the invention is the use of a silicon substrate for the formation of a nitride based MOSFET structure on a silicon substrate. In addition, such a nitride MOSFET transistors device structure allows for the simultaneous integration of silicon CMOS circuitry with GaN, AlN, InN, or InGaN MOSFET circuitry that is particularly useful in mixed signal and RF applications. It is well know by those skilled in the art that GaN and other compound semiconductors may be directly nucleated and grown on silicon by either MBE or by MOCVD epitaxial growth techniques.

A fifteenth aspect of the invention is the large reduction of surface states and associated traps that can limit the amount of microwave power that may be delivered by the invention. One aspect that sets this invention apart from other GaN HFETs is the use of an epitaxial oxide layer that largely reduces the amount of current compression or gain compression that is observed when comparing DC and microwave frequencies.

A sixteenth aspect of this invention is the use of an m-face AlN substrate or R-plane sapphire substrate that allows the growth of GaN, InGaN, AlN structures without polarization charge in the device structure that is more suitable for use in enhancement mode device structures.

A seventeenth aspect of the invention allows for the integration of the nitride MOSFET devices with passive components including inductors, capacitors, and transmission lines for the proper RF and microwave matching of the input and output impedance of microwave signals in these nitride MOSFETs. In addition the dielectrics utilized in the passive components may be of an electrically tunable nature that allows control circuitry to be used to adjust or tune the capacitance or inductance of the passive components integrated with the nitride MOSFET devices.

There has thus been outlined features of the invention in order that the detailed description thereof that follows may be better understood, and in order that the present contribution to the art may be better appreciated. There are, of course, additional features of the invention that will form the subject matter of the claims appended hereto. In this respect, before explaining at least one embodiment of the invention in detail, it is to be understood that the invention is not limited in its application to the details of construction and to the arrangements of the components set forth above or in the following description or illustrated in the drawings. The invention is capable of other embodiments and of being practiced and carried out in various ways. Also, it is to be understood that the phraseology and terminology employed herein are for the purpose of description and should not be regarded as limiting. As such, those skilled in the art will appreciate that the conception, upon which this disclosure is based, may readily be utilized as a basis for the designing of other structures, methods and systems for carrying out the several purposes of the present invention. It is important, therefore, that the claims be regarded as including such equivalent constructions insofar as they do not depart from the spirit and scope of the present invention.

### BRIEF DESCRIPTION OF THE DRAWINGS

A more complete understanding of the present invention may be derived by referring to the detailed description and claims when considered in connection with the figures, wherein like reference numbers refer to similar items throughout the figures, and:

FIG. 1 is a simplified cross sectional view of a self-aligned enhancement mode compound semiconductor MOSFET in accordance with a preferred embodiment of the present invention;

FIG. 2 is a simplified flow chart illustrating a method of manufacturing a self-aligned nitride compound semiconductor MOSFET in accordance with a preferred embodiment of the present invention. The exemplification set out herein illustrates a preferred embodiment of the invention in one form thereof, and such exemplification is not intended to be construed as limiting in any manner.

FIG. 3 is a simplified flow chart illustrating a method of manufacturing a self-aligned nitride compound semiconductor MOSFET in accordance with another preferred embodiment of the present invention. The exemplification set out herein illustrates a preferred embodiment of the invention in one form thereof, and such exemplification is not intended to be construed as limiting in any manner.

FIG. 4 is a sample layer structure of an InGaN channel MOSFET grown on a combined GaN AlN buffer layer that may be grown on SiC, Sapphire, or Silicon substrates. The layer structure shows a GaN layer just adjacent to the multilayer epitaxial oxide stack that forms the gate insulator structure. This device structure is designed to operate in depletion mode, but can also operate in enhancement mode if a large positive voltage is placed in the gate of the device.

FIG. 5 shows the DC transfer curves of the GaN MOSFET transistor device, and the amount of current compression at microwave frequencies that is expected without the use of a proper passivating layer on top of the GaN HFET device. The nitride MOSFET in this figure is operated in depletion mode with negative gate bias over much of its operating range.

FIG. 6 shows a comparison between the pulsed IV using (Vgs=0,Vds=0) and (Vgs=−9,Vds=−12.5) of the GaN MOSFET transistor structure shown in FIG. 4. The amount of current compression in the transfer curves of this device is shown by the ‘]’ bracket in the figure when the 2 layer epitaxial gate oxide that specifically consists of Ga-oxide/Ga—Gd-oxide is used as the gate insulator structure in the device.

FIG. 7 shows a sample layer structure for an AlGaN channel MOSFET grown on a native AlN substrate. In this device structure, an InGaN or GaN layer may be substituted for the AlGaN channel layer, the gate oxide layer depicted is actually comprised of a lower Ga-oxide layer and an upper Ga—Gd-oxide layer. In addition to Gd, the upper layer of the gate oxide may be formed using oxides of Hf, Sm, Sc, Gd, Lu and or other rare earth elements and combinations thereof. This example description is not meant to limit the gate oxide elemental combinations in the upper layer of the epitaxial gate oxide structure.

### DETAILED DESCRIPTION OF THE DRAWINGS

The present invention provides, among other things, a self-aligned enhancement mode metal-oxide-compound semiconductor FET and integrated circuit utilizing these nitride based MOSFETs. The MOSFET includes a epitaxial gate oxide passivating+insulating structure that is comprised of at least two layers. The first layer is most preferably one monolayer in thickness or approximately 3 angstroms thick but preferably less that 25 angstroms in thickness and composed substantially of indium oxide or gallium oxygen compounds including but not limited to stoichiometric In₂O₃, In₂O, Ga₂O₃ and Ga₂O, and possibly a lesser fraction of other indium and gallium oxygen compounds. The upper insulating layer in the gate insulating structure is composed of an insulator that does not intermix with the underlying indium gallium oxygen passivating structure. This upper layer must possess excellent insulating qualities, and is most typically composed of gallium oxygen and a third rare earth element Alternatively, the upper insulating layer may be comprised of gallium oxygen and one or more rare earth elements and that together form a ternary, quaternary etc. . . . insulating material layer. In another embodiment the upper insulating layer may also be composed of indium oxygen compounds with the addition of at least one or more rare earth element. Therefore the entire gate insulating structure is comprised of at least two layers where the lower layer directly adjacent to the compound semiconductor structure is comprised of indium oxygen or gallium oxygen and an upper layer comprised of at least two of the elements of indium, gallium, oxygen, sulfur, with the addition of at least one rare earth element. In addition an intermediate graded layer that is comprised of a fractional mixture of the lower and upper materials may also exist in the passivating and insulating structure for compound semiconductor structures. Together the initial indium oxygen or gallium oxygen layer, any intermediate graded layer and the top insulating region form both a indium gallium oxide insulating structure and the gate insulator region of a metal-oxide-compound semiconductor field effect transistor. The initial indium oxygen or gallium oxygen layer forms an atomically abrupt interface with the top layer of the compound semiconductor wafer structure, and does not introduce midgap surface states into the compound semiconductor material. A refractory metal gate electrode is preferably positioned on the upper surface of the gate insulator structure layer. The refractory metal is stable on the gate insulator structure layer at elevated temperature. Refractory metals with lower work functions such as iridium, ruthenium, platinum, molybdenum are most suitable for the formation of enhancement mode transistor devices in this metal oxide semiconductor transistor technology. Self-aligned source and drain areas, and source and drain contacts are positioned on the source and drain areas. In all embodiments preferred and otherwise, the metal-oxide-compound semiconductor transistor includes multi-layer gate insulator structure including an initial indium oxygen or gallium oxygen layer, intermediate transition layer, and upper insulating layer of 10-250 angstroms in thickness positioned on upper surface of a compound semiconductor heterostructure that form the gate insulator structure. The preferred embodiment also comprises a compound semiconductor heterostructure including a GaN, Alₓ Ga₁₋ₓN and In_{y} Ga_{1-y}N layers with or without n-type and/or p-type charge supplying layers which are grown on a compound semiconductor substrate, a refractory metal gate of Pt, Ir, W, Mo, Ru, Ta, WN, WSi, and combinations thereof with self aligned donor (n-channel FET) or acceptor (p-channel FET) regrown contact materials on implant regions, and source and drain ohmic contacts. In another preferred embodiment the GaN/Al_{y}Ga_{1-y}N compound semiconductor structure possess n-type charge in the channel of the structure that results from the piezoelectric strain in the compound semiconductor structure. In another preferred embodiment the a non-polar substrate such as an m-face or R-plane sapphire substrate is utilized so that there is no polarization charge supplied in the device layers of this structure.

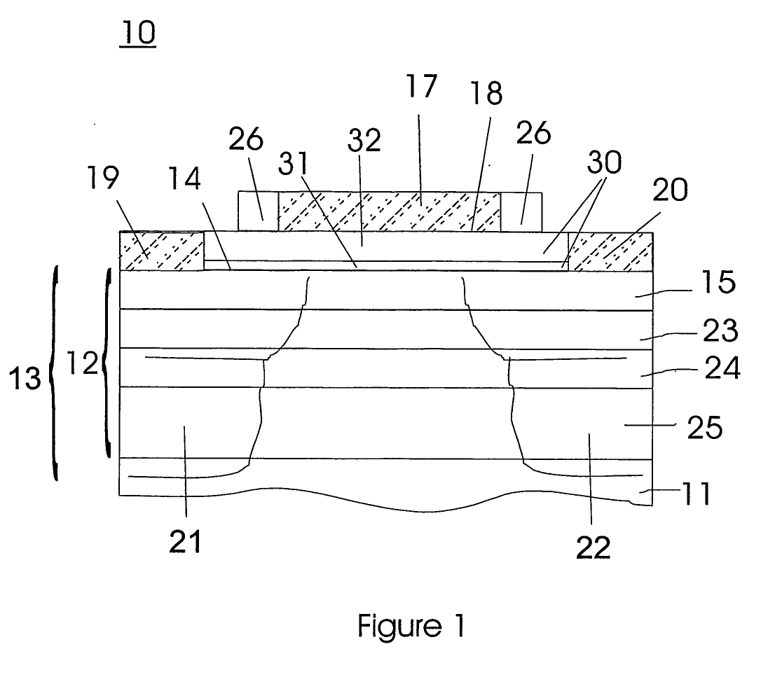

FIG. 1 is simplified cross sectional view of a self-aligned enhancement mode compound semiconductor MOSFET in accordance with a preferred embodiment of the present invention. Device 10 includes a compound semiconductor material, such as any nitride III-V material employed in any semiconductor device, represented herein by a III-V semiconductor or insulating substrate inclusing silicon, SOI, AlN, GaN, Sapphire, GaN-on-Sapphire etc. 11 and a compound semiconductor epitaxial layer structure 12. For the purpose of this disclosure, the substrate 11 and any epitaxial layer structure 12 formed thereon will be referred to simply as a compound semiconductor wafer structure which in FIG. 1 is designated 13. Methods of fabricating semiconductor wafer structure 13 include, but are not limited to, molecular beam epitaxy (MBE) and metal organic chemical vapor deposition (MOCVD), Chemical Beam Epitaxy (CBE) and the associated deposition techniques. It will of course be understood that in some specific applications, there may be no epitaxial layers present and upper surface of top layer 15 may simply be the upper surface of substrate 11.

Device 10 further comprises a gate insulator structures (30) that includes at least two or more layers. The first layer of the gate insulator structure (31) is composed entirely of indium gallium oxide compounds and is directly adjacent to and deposited upon the compound semiconductor structure. The second layer of the gate insulator structure (32) is composed of a compound of gallium, oxygen, and one or more rare earth elements, or gallium sulphur, and one or more rare earth elements from the periodic table. The initial gallium oxygen layer (31) forms an atomically abrupt interface 14 with the upper surface of top layer 15, the top layer of the compound semiconductor structure. A refractory metal gate electrode 17 which is stable in the presence of top insulating material at elevated temperature and further possess the proper work function that is positioned on upper surface 18 of the gate insulator structure. Dielectric spacers 26 are positioned to cover the sidewalls of metal gate electrode 17. Source and drain contacts 19 and 20 are deposited on self-aligned source and drain areas 21 and 22, respectively.

In a specific embodiment, the compound semiconductor epitaxial layer structure consists of a <11 angstrom GaN top layer (15), a <151 angstrom AlₓGa₁₋ₓN spacer layer (23), a <501 angstrom In_{y}Ga_{1-y}N channel layer (24), and an AlₓGa₁₋ₓN buffer layer (25) grown on a silicon, SOI, AlN, or GaN substrate (11). Top GaN layer (15) is used to form an atomically abrupt layer with the gallium oxide portion of the gate insulator structure with an abrupt interface with low defect density.

As a simplified example of fabricating a self-aligned enhancement mode compound semiconductor MOSFET in accordance with a preferred embodiment of the present invention, a III-V compound semiconductor wafer structure 13 with an atomically ordered pure and chemically clean upper surface of top layer 15 is prepared in an ultra-high vacuum semiconductor growth chamber and transferred via a ultra high vacuum transfer chamber to a second ultra high vacuum oxide and insulator deposition chamber. The initial indium oxygen or gallium oxygen layer (31) is deposited on upper compound semiconductor surface layer 15 using thermal evaporation from a high purity or vacuum deposition grade Ga₂O₃ and In₂O₃ sources that may be crystalline, polycrystalline, or amorphous material or from crystalline gadolinium gallium garnet, Ga₃Gd₅O₁₂, or indium gadolinium gamet, In₃Gd₅O₁₂. This initial gallium oxygen layer is deposited while holding the substrate temperature of the compound semiconductor structure at <580° C., and more preferably at a substrate temperature <495° C., and most preferably at a substrate temperature between 250° C. and 460° C. After the deposition of approximately 3 angstroms of indium gallium oxygen compounds in the insulator deposition chamber over a 2 to 5 minute period of time, deposition of the second insulator layer is initiated. The deposition of the second insulator layer starts by directing the flux from a low power oxygen plasma source into the ultra high vacuum system such that the oxygen plasma effluent and species are largely directed toward and impinging upon said compound semiconductor structure with initial gallium oxygen layer. The flux from the oxygen source that may include molecular oxygen, excited molecular oxygen, or atomic oxygen most typically produced using a plasma, or some combination of molecular and atomic oxygen, should be directed at the surface for between 2-5 seconds, subsequently followed by the co-evaporation of gallium oxygen compounds from Ga₂O₃, indium oxygen compounds from In₂O₃, and a third thermal evaporation or e-beam source that contains a rare-earth element (e.g. Gd) or rare earth oxide compound (Gd₂O₃). The flux beams from the oxygen source, In₂O₃, Ga₂O₃ and rare-earth evaporation source thermal evaporation sources are carefully balanced to provide a ternary insulator layer on top of the initial gallium oxygen layer on said compound semiconductor structure. As the deposition of the second insulator layer is initiated, the substrate temperature is simultaneously adjusted to provide an optimized substrate temperature for the deposition of this layer. In this example the substrate temperature required to deposit the gallium+oxygen+rare earth layer is <510° C. In another preferred embodiment this second insulating layer is comprised of gallium sulphur and at least and at least one rare earth element. In yet another preferred embodiment, this second insulating layer is comprised of gallium, oxygen, at least one rare earth element, and a fraction of indium adjusted to allow the layer to possess sufficient insulating properties. In yet another preferred embodiment, this second insulating layer is comprised of gallium, sulphur, at least one rare earth element, and an indium fraction adjusted to allow the layer to possess sufficient insulating properties. The deposition of this second insulator layer proceeds until the total insulator thickness of 50-250 angstroms is achieved. Shutters and valves are utilized to stop the deposition of the second insulting layer upon the deposition of the required thickness of the insulator layer. The substrate temperature is cooled in-vacuum to approximately 200° C., and the deposition of a refractory metal which is stable and does not interdiffuse with on the top layer of the gate insulator structure at elevated temperature such as Ir, Pt, Mo, Ru, Ta WSi, WN or combinations thereof is deposited on upper surface 18 of oxide layer 32 and subsequently patterned using standard lithography. The gate metal may be most easily formed using standard lift-off techniques common in compond semiconductor processing. Alternatively, the refractory metal layer may be etched until oxide layer 31 is exposed using a refractory metal etching technique such as a fluorine or halogen based dry etching process. The refractory metal etching procedure does not etch the oxide layer 31, thus, oxide layer 31 functions as an etch stop layer such that upper surface of top layer 15 remains protected by oxide layer 31. All processing steps are performed using low damage plasma processing. Self-aligned source and drain areas 21 and 22, respectively are realized by ion implantation of Si (n-channel device) and Be/F or C/F (p-channel device) using the refractory metal gate electrode 17 and the dielectric spacers 26 as implantation masks. Such ion implantation schemes are compatible with standard processing of complementary compound semiconductor heterostructure FET technologies and are well known to those skilled in the art. The implants are activated at 700-950° C. using rapid thermal annealing in an ultra high vacuum environment such that degradation of the interface 16 established between top layer 15 and oxide layer 31 is completely excluded. Finally, ohmic source and drain contacts 19 and 20 are deposited on the self-aligned source and drain areas 21 and 22, respectively. The devices may then be interconnected using the standard methods to those skilled in the art of integrated microelectronics and integrated circuit manufacture.

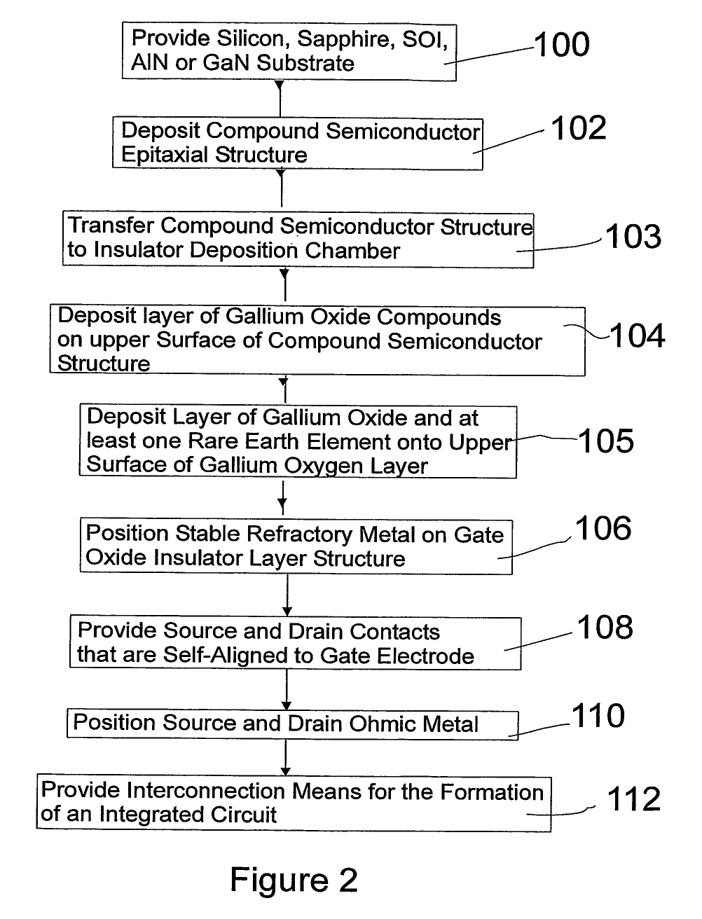

FIG. 2 is a simplified flow chart illustrating a method of manufacturing a self-aligned enhancement mode compound semiconductor MOSFET in accordance with a preferred embodiment of the present invention. In step 100, the process starts with a nitride based III-V substrate or with silicon, sapphire or SOI used as the substgrate. In step 102, a compound semiconductor wafer structure is produced using standard epitaxial growth methods in the art. In step 104, a layer consisting of gallium oxygen compounds including but not limited to Ga₂O₃, and Ga₂O is deposited on upper surface of said compound semiconductor wafer structure. In step 104, an insulating layer of gallium oxygen and one or more rare earth elements is deposited on the upper surface of the initial gallium oxygen compound layer. The gallium oxide gate insulator structure is formed in steps 104 and 105. In step 106, a stable refractory gate metal is positioned on upper surface of said gate insulator structure. In step 108, source and drain ion implants are provided self-aligned to the gate electrode. In step 110, source and drain ohmic contacts are positioned on ion implanted source and drain areas.

Step 102 includes the preparation and epitaxial growth of an atomically ordered and chemically clean upper surface of the compound semiconductor wafer structure. Step 103 preferably comprises thermal evaporation from a purified and crystalline gadolinium gallium garnet or Ga₂O₃ source on an atomically ordered and chemically clean upper surface of the compound semiconductor wafer structure. Step 105 comprises the formation of a gallium+oxygen+rare earth elemental insulating layer formed through the simultaneous vacuum evaporation of gallium oxygen species, and at least one rare earth element or oxide such as gadolinium, hafnium with the simultaneous oxidation using the effluent of an oxygen gas delivered as excited molecules, atomic oxygen, or unexcited molecules directed in simultaneous combination with other thermal evaporation sources toward substrate 100. The initial gallium oxygen compound layer of the gate insulator structure preferably functions as an etch stop layer such that the upper surface of the compound semiconductor wafer structure remains protected by the gate oxide during and after gate metal etching. The refractory gate metal desirably does not react with or diffuse into the gate oxide layer during high temperature annealing of the self-aligned source and drain ion implants. The quality of the interface formed by the gate oxide layer and the upper surface of the compound semiconductor structure is desirably preserved during high temperature annealing of the self-aligned source and drain ion implants. The self-aligned source and drain implants are desirably annealed at approximately 700-1350° C. in an ultra high vacuum environment or in a balanced environment of nitrogen, argon, oxygen and/or hydrogen. The self-aligned source and drain implants are desirably realized by positioning dielectric spacers on the sidewalls of the refractory gate metal.

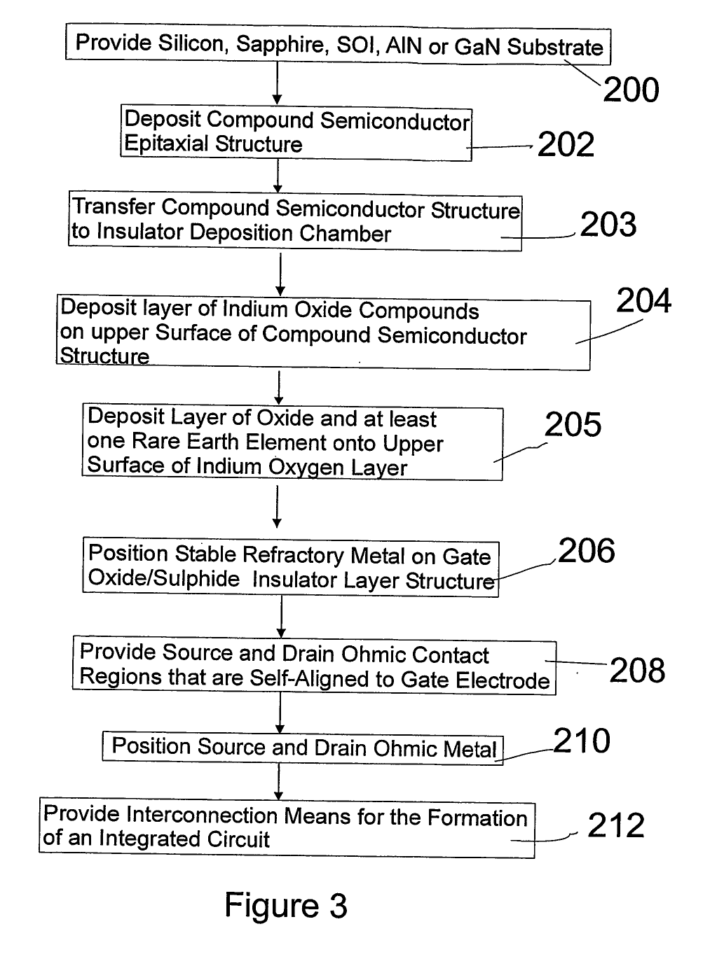

FIG. 3 is a simplified flow chart illustrating a method of manufacturing a self-aligned enhancement mode compound semiconductor MOSFET in accordance with another preferred embodiment of the present invention. In step 202, a compound semiconductor wafer structure is produced using standard epitaxial growth methods in the art. In step 203, a layer consisting of indium oxygen compounds including but not limited to, In₂O₃ and In₂O is deposited on upper surface of said compound semiconductor wafer structure. In step 204, an insulating layer of indium and oxygen and is deposited on the upper surface of the initial nitride compound semiconductor layer. The insulating oxide layer that is comprised of oxygen and at least one rare earth gate insulator structure is formed in steps 204 and 205. In step 206, a stable refractory gate metal with the proper work function is positioned on upper surface of said gate insulator structure. In step 208, source and drain ion implants are provided self-aligned to the gate electrode. In step 210, source and drain ohmic contacts are positioned on ion implanted source and drain areas.

In a preferred embodiment, step 200 provides a substrate such as silicon, sapphire, SOI, AlN, or GaN or various GaN substrates including: GaN-on-Sapphire, GaN—AlN-on-Sapphire, GaN—AlN-on-SiC, GaN—AlN—C-Silicon, and GaN-on-GaN. Step 202 includes the preparation and epitaxial growth of an atomically ordered and chemically clean upper surface of the compound semiconductor wafer structure. Step 204 preferably comprises thermal evaporation from a purified and crystalline gadolinium indium garnet or In₂O₃ source that is amorphous, crystalline, or polycrystalline toward an atomically ordered and chemically clean upper surface of the nitride semiconductor wafer structure. Step 204 comprises the formation of a indium+oxygen elemental layer formed typically through vacuum evaporation of indium oxygen species. Step 205 include the formation of an addition oxide layer that does not include indium but may include one or more rare earth elements. The initial indium gallium oxygen compound layer of the gate insulator structure preferably functions as an etch stop layer such that the upper surface of the compound semiconductor wafer structure remains protected by the gate oxide during and after gate metal etching. The refractory gate metal desirably does not react with or diffuse into the second or upper oxide layer during high temperature annealing of the self-aligned source and drain ion implants. The quality of the interface formed by the gate oxide layer and the upper surface of the compound semiconductor structure is desirably preserved during high temperature annealing of the ohmic contact metal or ohmic contact regrowth or annealing of self-aligned source and drain ion implants. The self-aligned source and drain implants are desirably annealed at approximately 700-950° C. in an ultra high vacuum environment. The self-aligned source and drain implants are desirably realized by positioning dielectric spacers on the sidewalls of the refractory gate metal.

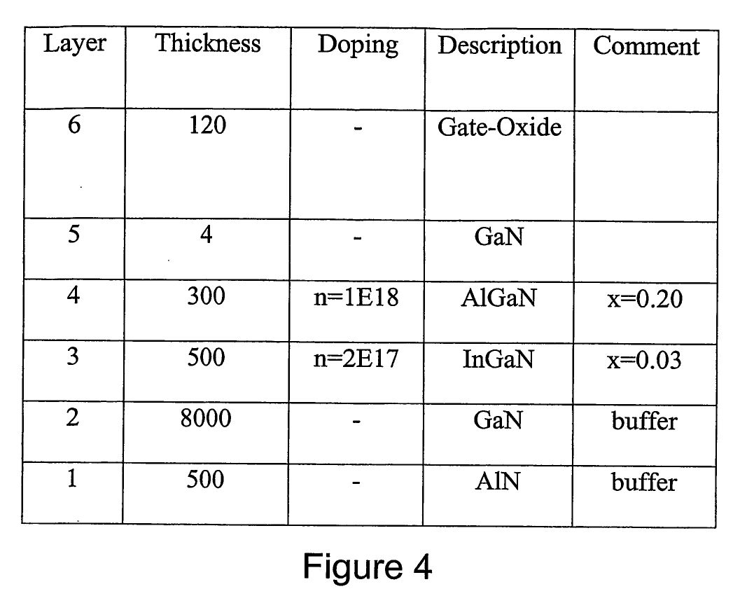

FIG. 4 provide a table that contains a layer structure for the nitride semiconductpr structure and the epitaxial gate oxide structure as a whole without breaking out individual layers in the gate-oxide portion of the layer structure. This structure has an InGaN channel and a AlGaN layer to provide charge piezoelectrically to the device structure.

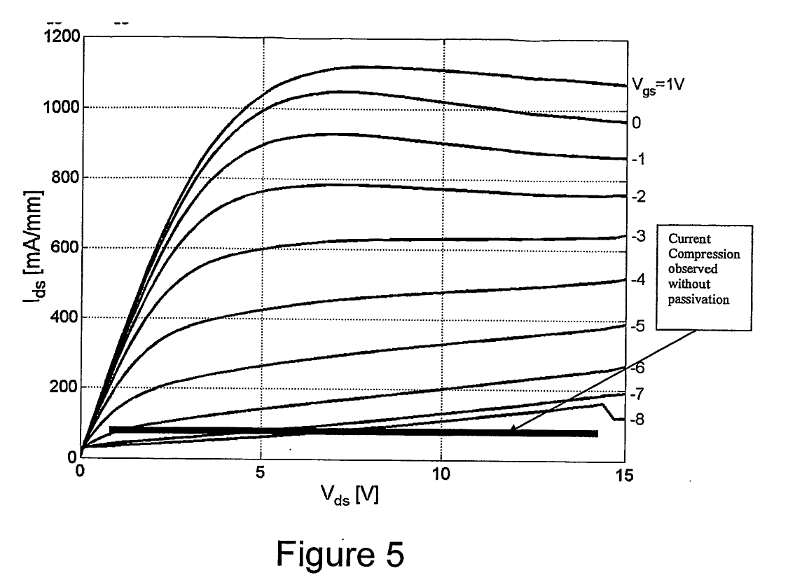

FIG. 5 shows the DC transfer curves of a working NMOS InGaN channel MOSFET. The device is shown to be operating in depletion mode as indicated by the mostly negative gate bias. The thick black line illustrates the level of current compression or gain compression that is expected at microwave frequencies when the epitaxial gate oxide that is the subject of this invention and no other passivation technique is utilized on a GaN HFET transistor device.

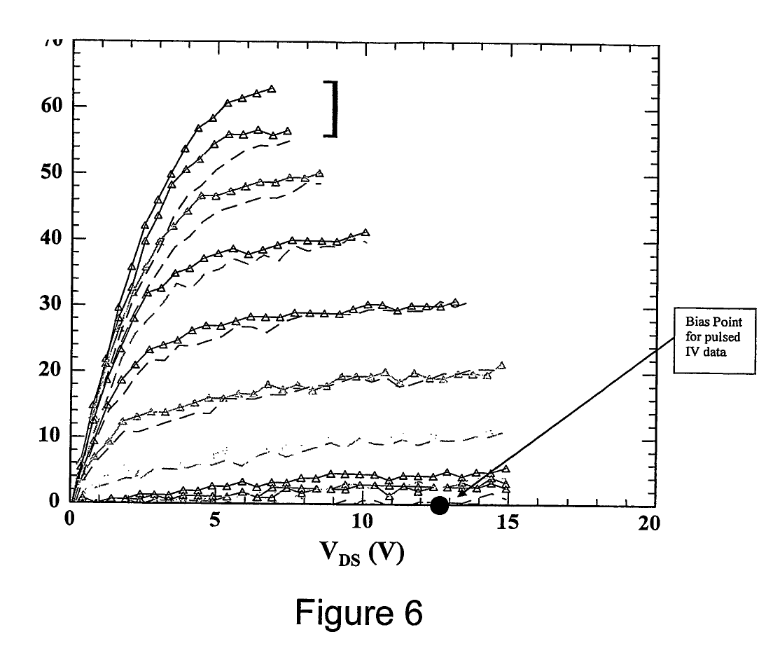

FIG. 6 shows the pulsed IV of the device structure shown in FIG. 4. The black bracket illustrates the approximate difference between the upper solid line (DC IV) and the first dashed line (Pulse IV) of the same transfer curve. The pulsed IV data shows the level of measured current compression that may be observed experimentally in the nitride MOSFET device that is the subject of this invention.

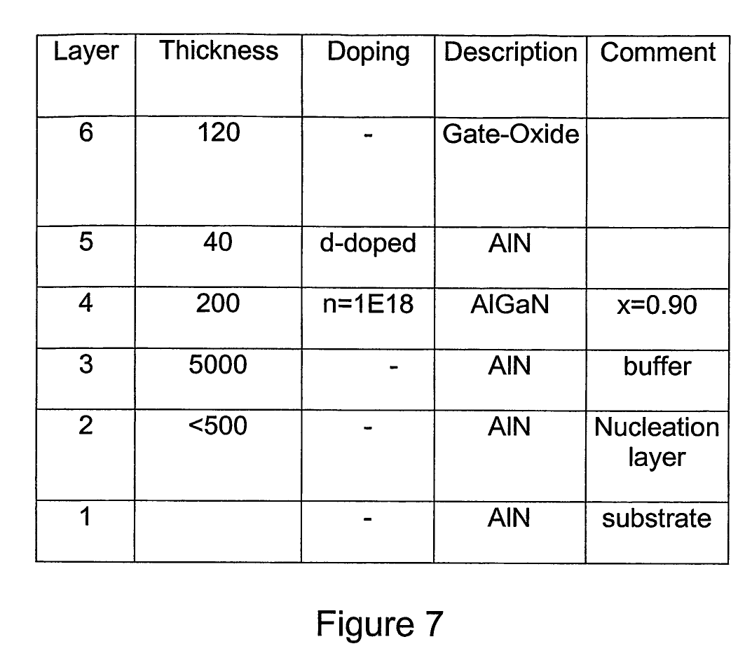

FIG. 7 shows a table that contains a layer structure that includes an AlN substrate. In this structure only the AlGaN channel and the epitaxial gate oxide are materials that are not lattice matched to the native AlN substrate. In this device structure the AlGaN channel material is only one possible channel material. In particular, GaN and InGaN channel materials could also be easily utilized in this device structure. The doping in the structure may also be adjusted in the n-type and p-type sense on a layer by layer basis as is necessary to obtain optimized device operation.

It will now be understood that what has been disclosed herein includes new compound semiconductor devices and methods of fabrication. Those having skill in the art to which the present invention relates will now as a result of the teaching herein perceive various modifications. Accordingly, all such modifications are deemed to be within the scope of the invention that is to be limited only by the claims.

Thus, new and improved compound semiconductor devices and methods of fabrication are disclosed. The new and improved self-aligned enhancement mode metal-oxide-compound semiconductor heterostructure field effect transistors enable stable and reliable device operation, provide optimum compound semiconductor device performance for high power/high performance complementary circuits and architectures, keep interconnection delay in VLSI and ULSI under control, and provide optimum efficiency and output power for RF and microwave applications as well as for digital integrated circuits that require very high integration densities.

These improvements essentially solve or overcome the problems of the prior art, such as high gate leakage in compound semiconductor HFET devices, low integration densities, dc electrical instability, microwave dispersion, and electrical hysteresis, and therefore provide a highly useful invention. While we have shown and described specific embodiments of the present invention, further modifications and improvements will occur to those skilled in the art. We desire it to be understood, therefore, that this invention is not limited to the particular forms shown and we intend in the appended claims to cover all modifications that do not depart from the spirit and scope of this invention.

1. A metal-oxide-compound semiconductor field effect transistor structure comprising:
a nitride compound semiconductor wafer structure having an upper surface;
a gate insulator structure comprising a first layer and a second layer;
wherein said first layer substantially comprises oxygen and at least one of gallium and indium, said first layer in contact with said upper surface; and
wherein said second layer comprises at least one insulating compound.

2-70. (canceled)

71. The structure of claim 1 wherein said at least one insulating compound comprises at least one indium and gallium.

72. The structure of claim 71 wherein said at least one insulating compound comprises at lease one rare earth element.

73. The structure of claim 1 wherein said at least one insulating compound comprises at least one of oxygen and sulfur.

74. The structure of claim 1 wherein said at least one insulating compound comprises at least one rare earth element.

75. The structure of claim 1 further comprising a gate electrode positioned on said gate insulator structure.

76. The structure of claim 72 further comprising source and drain regions self-aligned to said gate electrode.

77. The structure of claim 72 wherein said gate electrode comprises a metal selected from the group refractory gate metals and combinations thereof.

78. The structure of claim 1 further comprising a substrate.

79. The structure of claim 78 wherein said nitride compound semiconductor wafer structure is built on said substrate.

80. The structure of claim 78 wherein said substrate is form from a member selected from the group consisting of sapphire, silicon, silicon on insulator, aluminum nitride, and gallium nitride.

81. The structure of claim 1 further comprising a layer between said first layer and said second layer having a composition intermediate between the compositions of said first layer and said second layer.

82. The structure of claim 1 wherein said first layer has a thickness of more than 3 angstroms and less than 25 angstroms.

83. The structure of claim 1 wherein said gate insulator structure has a thickness of 10-300 angstroms.

84. The structure of claim 1 wherein said upper surface comprises GaN.

85. The structure of claim 1 wherein said upper surface comprises InxGa1-xN.

86. The structure of claim 1 wherein said upper surface comprises AlxGa1-xN.

87. An field effect transistor comprising the structure of claim 1.

88. An integrated circuit comprising the structure of claim 1.

89. A method of making a metal-oxide-compound semiconductor field effect transistor structure comprising:
providing a nitride compound semiconductor wafer structure having an upper surface;
providing a gate insulator structure comprising a first layer and a second layer;
wherein said first layer substantially comprises oxygen and at least one of gallium and indium, said first layer in contact with said upper surface; and
wherein said second layer comprises at least one insulating compound.

90. A method of making a metal-oxide-compound semiconductor field effect transistor structure comprising:
providing a nitride compound semiconductor wafer structure having an upper surface;
depositing a gate insulator structure comprising depositing a first layer and depositing a second layer;
wherein said depositing said first layer comprises depositing oxygen and at least one of gallium and indium, onto said upper surface; and
wherein depositing said second layer comprises depositing at least one insulating compound onto said first layer.

91. A method of using a metal-oxide-compound semiconductor field effect transistor structure, said structure comprising:
a nitride compound semiconductor wafer structure having an upper surface;
a gate insulator structure comprising a first layer and a second layer;
wherein said first layer substantially comprises oxygen and at least one of gallium and indium, said first layer in contact with said upper surface;
wherein said second layer comprises at least one insulating compound; and
said method comprising applying a voltage to said gate insulator structure.
